(19) United States
(12) Patent Application Publication
(10) Pub. No.: US 2017/0243888 A1
(43) Pub. Date: Aug. 24, 2017

(54) LAYOUT STRUCTURE FOR SEMICONDUCTOR INTEGRATED CIRCUIT

(71) Applicant: SOCIONEXT INC., Kanagawa (JP)

(72) Inventor: Hiroyuki SHIMBO, Kyoto (JP)

(21) Appl. No.: 15/591,923

(22) Filed: May 10, 2017

Related U.S. Application Data
(63) Continuation of application No. PCT/JP2015/005003, filed on Oct. 1, 2015.

(30) Foreign Application Priority Data
Nov. 12, 2014 (JP) 2014-229804

(51) Int. Cl. H01L 27/12; H01L 23/66; H01L 27/02

(52) U.S. Cl. CPC H01L 27/1203; H01L 27/0207; H01L 23/66; H01L 2223/6677

(57) ABSTRACT

In a circuit block, a plurality of cell rows, each being comprised of a plurality of standard cells arranged in a first direction, are arranged in a second direction perpendicular to the first direction, thereby forming a circuit of SOI transistors. The circuit block includes a plurality of antenna cells, each including an antenna diode provided between a power supply line and a substrate or a well. In at least a part of the circuit block, the antenna cells are arranged at constant intervals in at least one of the first and second directions.

### CROSS-REFERENCE TO RELATED APPLICATION

This is a continuation of International Application No. PCT/JP2015/005003 filed on Oct. 1, 2015, which claims priority to Japanese Patent Application No. 2014-229804 filed on Nov. 12, 2014. The entire disclosures of these applications are hereby incorporated by reference.

### BACKGROUND

The present disclosure relates to a layout structure for a semiconductor integrated circuit including transistors with a silicon-on-insulator (SOI) structure (hereinafter referred to as “SOI transistors”).

FIG. 7 is a cross-sectional view illustrating a configuration for an SOI transistor. As shown in FIG. 7, the SOI transistor includes a buried insulator (typically a buried oxide) 41 in a substrate or a well, a silicon thin film 42 formed on the buried insulator 41, and a transistor device comprised of a gate G, a source S, and a drain D on the silicon thin film 42. This structure tends to intensify an electric field generated in a channel region between the source and drain, thus contributing to the performance enhancement of the transistor. Note that a type of SOI structure having so thin a silicon film 42 as to fully deplete the channel region is called a fully-depleted silicon-on-insulator (FD-SOI).

Meanwhile, a semiconductor device manufacturing process may sometimes cause a so-called “antenna error.” The antenna error refers to a phenomenon that a transistor's gate dielectric under its gate electrode suffers either breakdown or damage due to the influx, into the gate electrode, of electric charges generated by plasma in the ambient during the manufacturing process of the transistor and collected in the metal wires of the transistor that are electrically connected to the gate electrode. In the case of an SOI transistor, the possibility of such antenna errors' occurring in not only the gate dielectric but also the buried insulator under the source or drain needs to be taken into account. The reason is that those electric charges collected in the metal wires of the transistor being manufactured also flow into the source or drain electrically connected to the metal wires to cause breakdown or damage to the buried insulator under a doped layer serving as the source or drain.

Thus, in order to avoid causing such antenna errors in an SOI transistor, Japanese Unexamined Patent Publication No. 2003-133559 discloses a technique for inserting an antenna diode for dissipating those electric charges into the substrate.

Japanese Unexamined Patent Publication No. 2003-133559, however, fails to disclose how to actually insert such an antenna diode into a semiconductor integrated circuit including SOI transistors.

Thus, the present disclosure provides a layout structure for a semiconductor integrated circuit including SOI transistors with such antenna errors that could occur in the buried insulator under the source or drain taken into account.

### SUMMARY

An aspect of the present disclosure provides a layout structure for a semiconductor integrated circuit including silicon-on-insulator (SOI) transistors. The structure includes a circuit block in which a plurality of cell rows, each being comprised of a plurality of standard cells arranged in a first direction, are arranged in a second direction that is perpendicular to the first direction, thereby forming a circuit of the SOI transistors. The circuit block comprises a plurality of antenna cells, each including an antenna diode formed between a power supply line for supplying power to the circuit block and a substrate or a well. In at least a part of the circuit block, the antenna cells are arranged at constant intervals in at least one of the first and second directions.

According to this aspect, a circuit block as an arrangement of a plurality of cell rows includes antenna cells, each including an antenna diode provided between a power supply line and a substrate or a well. The antenna cells are arranged at constant intervals in at least one of a first direction in which standard cells are arranged in each cell row or a second direction in which those cell rows are arranged. This layout structure is implemented by regular placement of antenna cells during a physical design process of the circuit block. This provides a technique for avoiding causing antenna errors without prolonging the design turnaround time (TAT) irrespective of the circuit area or shape of the circuit block.

The present disclosure provides a technique for avoiding causing antenna errors without prolonging the design TAT for a semiconductor integrated circuit including SOI transistors.

### BRIEF DESCRIPTION OF THE DRAWINGS

FIG. 1A is a plan view illustrating an exemplary layout structure for a semiconductor integrated circuit according to an embodiment, and FIG. 1B is a plan view illustrating an exemplary configuration for an antenna cell included in the layout structure shown in FIG. 1A.

FIG. 2 is a plan view illustrating a detailed structure of a circuit block including antenna cells.

FIG. 3 is a cross-sectional view illustrating a detailed structure of the circuit block including antenna cells.

FIG. 4 is a plan view illustrating an exemplary layout structure for a semiconductor integrated circuit according to another embodiment.

FIG. 5A is a plan view illustrating an exemplary layout structure for a semiconductor integrated circuit according to still another embodiment, and FIG. 5B is a plan view illustrating an exemplary configuration for an antenna cell with a TAP function included in the layout structure shown in FIG. 5A.

FIG. 6A is a plan view illustrating an exemplary layout structure for a semiconductor integrated circuit according to yet another embodiment, and FIG. 6B is a plan view illustrating an exemplary configuration for an antenna cell included in the layout structure shown in FIG. 6A.

FIG. 7 is a cross-sectional view illustrating an SOI transistor.

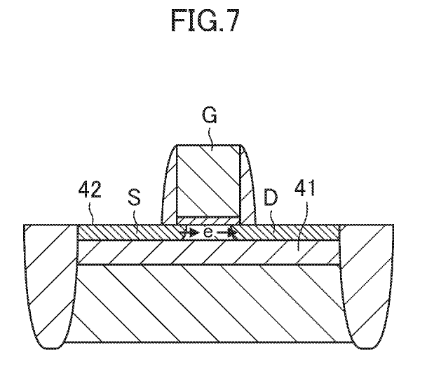

### DETAILED DESCRIPTION

Embodiments of the present disclosure will now be described with reference to the accompanying drawings.

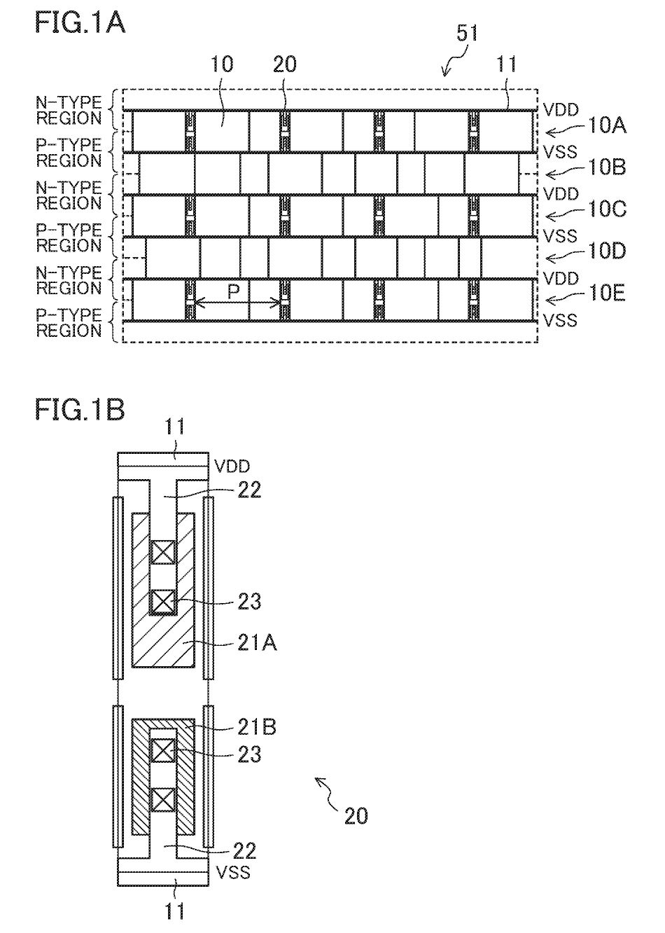

FIG. 1A is a plan view illustrating an exemplary layout structure for a semiconductor integrated circuit according to an embodiment. In FIG. 1A, schematically illustrated is a single circuit block 51 for a semiconductor integrated circuit. In this circuit block 51, five cell rows 10A, 10B, 10C, 10D, and 10E, each being comprised of a plurality of standard cells 10 that are arranged side by side horizontally (corresponding to the first direction) in FIG. 1A, are arranged vertically (corresponding to the second direction) in FIG. 1A. Note that neither the internal configuration nor wiring of the standard cells 10 is illustrated in FIG. 1A. The transistors included in each of those standard cells 10 have the SOI structure described above. Thus, a circuit of SOI transistors is formed in this circuit block 51. Power supply lines 11 for supplying either a supply potential VDD or a ground potential VSS to the circuit block 51 are arranged to extend horizontally between the cell rows. In these cell rows 10A-10E, P-type regions where N-channel transistors are arranged alternate every row with N-type regions where P-channel transistors are arranged. Each of the power supply lines 11 is shared by an associated pair of cell rows located over and under the power supply line 11. In this embodiment, an N-well to serve as an N-type region is supposed to be defined on a P-type substrate to serve as a P-type region.

In the circuit block 51 shown in FIG. 1A, arranged are antenna cells 20. As used herein, the “antenna cell” refers to a cell including an antenna diode configured to dissipate electric charges collected in a metal wire into either a substrate or a well. FIG. 1B is a plan view illustrating an exemplary configuration for the antenna cell 20. The antenna cell 20 shown in FIG. 1B includes doped regions 21A and 21B, which are defined on the substrate or well with no buried insulator interposed between them. Specifically, in this example, the doped region 21A is a region doped with a P-type dopant and defined on an N-well, while the doped region 21B is a region doped with an N-type dopant and defined on a P-type substrate. Each of these doped regions 21A and 21B is connected to an extension 22 of an associated power supply line 11 via contacts 23. That is to say, in the antenna cell 20 shown in FIG. 1A, an antenna diode is formed between each power supply line 11 and the substrate or well.

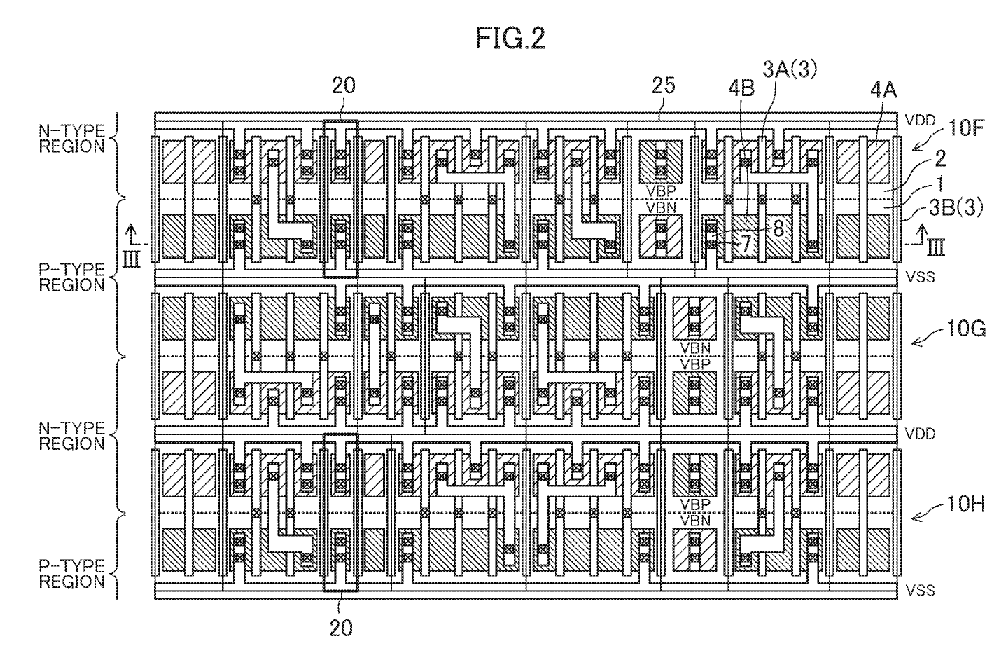

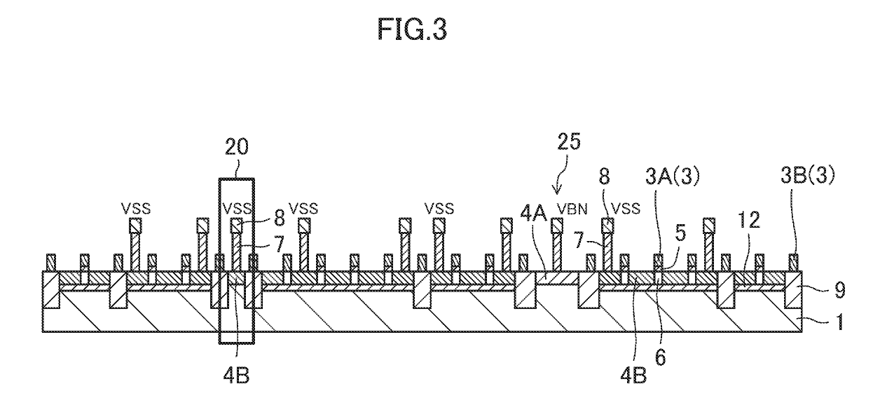

FIGS. 2 and 3 illustrate a detailed structure for a circuit block including antenna cells. FIG. 2 is a plan view illustrating a detailed layout for the circuit block, and FIG. 3 is a cross-sectional view taken along the plane III-III shown in FIG. 2. In FIG. 2, three cell rows 10F, 10G, and 10H, each extending horizontally in FIG. 2, are arranged vertically in FIG. 2. A cross section of the P-type region of the cell row 1OF is illustrated in FIG. 3. As shown in FIG. 3, in the P-type region, a buried oxide 12, an exemplary buried insulator, is provided in the P-type substrate 1, and an N-type doped layer 4B to serve as a source or drain for N-channel transistors has been formed on the buried oxide 12. Although its cross section is not shown in FIG. 3, in the N-type region, a buried oxide has been formed in an N-well 2, and a P-type doped layer 4A to serve as a source or drain for P-channel transistors has been formed on the buried oxide. Gates are identified by the reference numeral 3 and may be made of polysilicon, for example. The gates 3 include gates 3A, each of which forms part of a transistor, and dummy gates 3B, none of which forms any transistor. A gate oxide 5 has been formed as an exemplary gate dielectric under the gate 3A of each transistor, and a channel region 6 has been defined under the gate oxide 5. A portion of the doped layer 4A, 4B to serve as a source or drain for transistors, for example, is connected to the extension 8 of the power supply line via contacts 7. The reference numeral 9 denotes shallow trench isolations (STIs).

An antenna cell 20 is inserted into the cell row 10F. As shown in FIG. 3, no buried oxide 12 has been formed in the antenna cell 20, and the N-type doped layer 4B is directly in contact with the P-type substrate 1. A TAP cell 25 with a TAP function producing substrate potentials VBP, VBN is also inserted into the cell row 10F. No buried oxide 12 has been formed for the TAP cell 25, either, and the P-type doped layer 4A is directly in contact with the P-type substrate 1.

In the configuration shown in FIG. 1A, the antenna cells 20 are arranged regularly in the circuit block 51. Specifically, the antenna cells 20 are arranged at constant intervals P horizontally (i.e., in the direction in which the standard cells 10 are arranged). Also, the antenna cells 20 are provided for the cell rows 10A, 10C, and 10E, and arranged every other row vertically in FIG. 1A. In other words, the antenna cells 20 are arranged at constant intervals both in the first direction in which the standard cells 10 are arranged and in the second direction in which the cell rows 10A-10E are arranged.

Now, it will be described what significance such a regular arrangement of the antenna cells 20 has according to the present disclosure.

In a semiconductor integrated circuit comprised of transistors with a so-called “bulk structure,” only the possibility of antenna errors' occurring in their gate dielectric needs to be taken into account. That is why checking the circuit for any antenna errors, named “antenna inspection,” is usually performed on a circuit block, of which the operating timings have already converged after a placement of standard cells and routing have been done. Specifically, the antenna inspection is executed by detecting, based on a given antenna ratio, any spots that would possibly cause antenna errors, inserting antenna cells into the vicinity of those spots, and then routing and connecting the antenna diodes.

Meanwhile, a semiconductor integrated circuit comprised of SOI transistors should be free from antenna errors in not only its gate dielectric but also the buried insulator under its doped layer as well. For example, when a power supply line is provided for an M1 layer (that is the lowest-level metal interconnect layer) within the circuit block, electric charges collected in this power supply line will flow into a portion of the doped layer to function as the source. At this point in time, antenna errors could occur in the buried insulator under that portion of the doped layer to function as the source.

In this case, attempting to fix the errors by inserting antenna cells into those spots that would possibly cause antenna errors as in the known art mentioned above would pose the following problems. First of all, the number of antenna cells to be inserted increases proportionally to the total area of the M1 power supply lines to be charged, which increases with the area of the circuit block. That is why the larger the area of the circuit block, the greater the number of antenna cells to be inserted. This more and more frequently creates the need for relocating standard cells that have already been placed at the destinations of the antenna cells, thus causing operating timing errors of the circuit or prolonging the design turnaround time (TAT). In a worst case, inability of inserting any antenna cells could hamper the physical design of the circuit block utterly.

Furthermore, power supply lines include not only the power supply lines to be placed within the circuit block but also chip-level power supply lines to be routed at a higher level. The chip-level power supply lines are a high-order power supply structure for connecting together the power supplies of multiple circuit blocks. The chip-level power supply lines should have resistance low enough to curb a voltage drop, and therefore, have a broad line width, a high wiring density, and an extremely wide wiring area. That is why the chip-level power supply lines would have a huge quantity of electric charges collected. However, it is not until the chip-level design is completed that antenna errors caused by the huge quantity of electric charges collected in those lines are detected in the buried insulator. Therefore, the conventional technique of attempting to fix the antenna errors after having spotted them would require the designer to go back from the chip-level design to the block design, thus leading to a significantly prolonged design TAT.

Thus, to overcome these problems, the present disclosure adopts the following technique. In general, an antenna error is determined by the antenna ratio, i.e., the ratio of the area of a metal wire to the area of the doped layer of an antenna diode connected to the metal wire. That is why at the stage of physical circuit block design, the placement density of antenna cells with antenna diodes is determined in accordance with an antenna rule, and the antenna cells are placed regularly to meet the maximum allowable placement density. This allows only a power supply line with a predetermined area or less to be connected to each antenna cell, thus limiting the antenna ratio to a predetermined value or less with reliability. This technique dramatically decreases the likelihood of causing antenna errors irrespective of the circuit area or block shape, thus substantially preventing the circuit's operating timings or design TAT from being affected negatively. In addition, this can also eliminate the need for inserting an excessive number of antenna cells and therefore can cut down the chip area effectively as well.

Furthermore, this technique is applicable to not just the power supply lines within the circuit block but also the chip-level power supply lines as well. A specific exemplary application of this technique is as follows.

Suppose a power supply mesh having a regular grid pattern in which power supply lines are arranged at predetermined intervals is laid out on a circuit block. The power supply mesh is connected to the doped layer over the buried oxide in the SOI structure via the power supply lines in the circuit block. The wiring area S0 of the power supply mesh per unit area is constant on the circuit block, since the power supply mesh is regularly laid out on the circuit block. That is why if the doped layer area of an antenna diode per unit area is S1 and the circuit block area is A, the antenna ratio R is given by the following equation:

R=S0×A/S1×A=S0/S1

The upper limit of the antenna ratio R is defined by the antenna rule. Thus, the lower limit of the doped layer area S1 of an antenna diode per unit area is automatically determined by the area S0 of the power supply mesh per unit area. Then, antenna cells with antenna diodes just need to be placed in the circuit block such that the doped layer area S1 becomes equal to or greater than the lower limit defined by the antenna rule and the wiring area S0. For example, the antenna cells 20 may be placed every predetermined number of cell rows at constant intervals P in the arrangement direction of the standard cells 10 as shown in FIG. 1A.

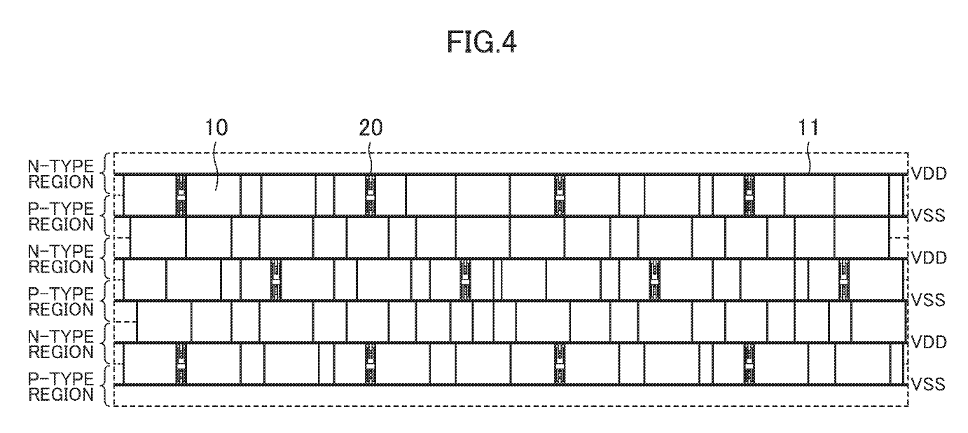

The regular arrangement of the antenna cells 20 does not have to be the layout shown in FIG. 1A. Alternatively, the antenna cells 20 may also be placed in a hound's tooth check as shown in FIG. 4. Adopting the arrangement pattern shown in FIG. 4 allows the antenna cells 20 to be easily placed at a uniform density if the number of antenna cells 20 required is relatively small.

Furthermore, the antenna cells 20 do not have to be regularly placed in the same pattern over the entire circuit block, but may also be placed regularly in one pattern in one part of the circuit block and placed in a different pattern in another part of the circuit block. For example, the arrangement interval of the antenna cells 20 in the arrangement direction of the standard cells 10 may be changed from one area in the circuit block to another. Alternatively, the interval between the cell rows to have the antenna cells 20 may be changed from one area in the circuit block to another as well.

In other words, if at least three antenna cells are arranged at constant intervals within a cell row, it can be said that the antenna cells are arranged regularly according to the technique of the present disclosure. Naturally, all antenna cells may be arranged at constant intervals in that cell row. Also, if antenna cells are arranged at regular cell row intervals (e.g., every other row) in at least three cell rows, then it can also be said that the antenna cells are arranged regularly according to the technique of the present disclosure. Naturally, antenna cells may also be arranged at regular cell row intervals in all of the cell rows of the entire circuit block.

(First Alternative Layout Structure)

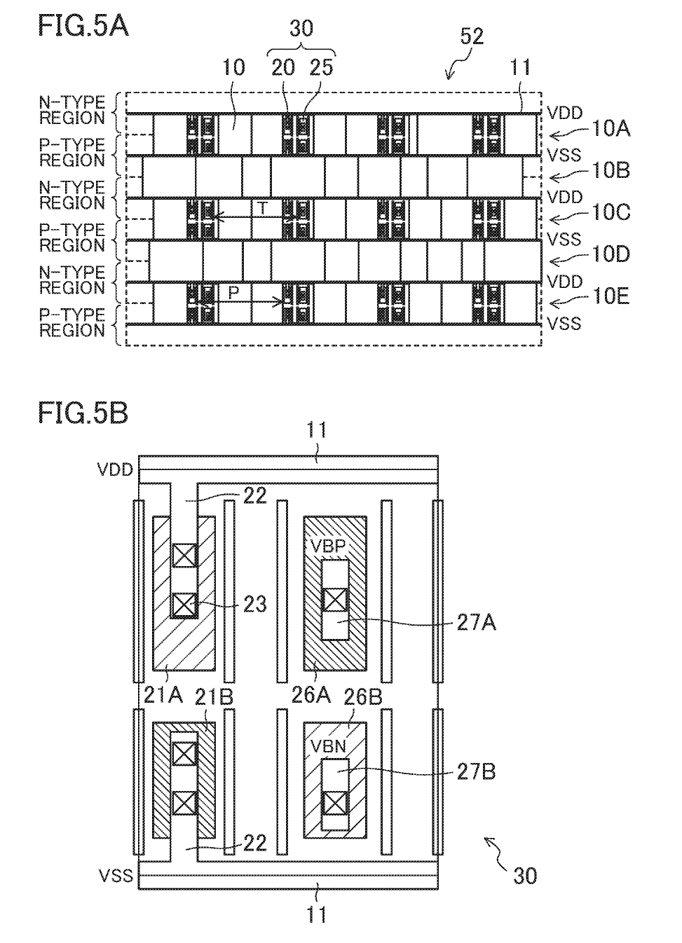

FIG. 5A is a plan view illustrating an alternative exemplary layout structure for a semiconductor integrated circuit according to an embodiment. In FIG. 5A, illustrated is a single circuit block 52 for a semiconductor integrated circuit. As in the circuit block 51 shown in FIG. 1A, five cell rows 10A, 10B, 10C, 10D, and 10E, each being comprised of a plurality of standard cells 10 that are arranged horizontally (corresponding to the first direction) in FIG. 5A, are arranged vertically (corresponding to the second direction) in FIG. 5A. Note that neither the internal configuration nor wiring of the standard cells 10 is illustrated in FIG. 5A. The transistors included in each of those standard cells 10 have the SOI structure described above. Thus, a circuit of SOI transistors is formed in this circuit block 52. Power supply lines 11 for supplying either a supply potential VDD or a ground potential VSS to the circuit block 52 are arranged to extend horizontally between the cell rows. In these cell rows 10A-10E, P-type regions alternate with N-type regions every row. Each of the power supply lines 11 is shared by an associated pair of cell rows located over and under the power supply line. In this embodiment, an N-well to serve as an N-type region is supposed to be defined on a P-type substrate to serve as a P-type region.

In the circuit block 52 shown in FIG. 5A, the antenna cells 20 are arranged as regularly as in the circuit block 51 shown in FIG. 1A. Specifically, the antenna cells 20 are arranged at constant intervals P horizontally (i.e., in the direction in which the standard cells 10 are arranged). Also, the antenna cells 20 are provided for the cell rows 10A, 10C, and 10E, and arranged every other row vertically in FIG. 5A. In other words, the antenna cells 20 are arranged at constant intervals both in the first direction in which the standard cells 10 are arranged and in the second direction in which the cell rows 10A-10E are arranged. The significance of such a regular arrangement of the antenna cells 20 is just as described above.

In the circuit block 52 shown in FIG. 5A, a TAP cell 25 having a TAP function of supplying a substrate potential VBP or VBN is further arranged adjacent to each antenna cell 20. That is to say, the TAP cells 25 are also arranged horizontally at constant intervals T in the cell rows 10A, 10C, and 10E, i.e., every other row vertically.

To implement the arrangement of the antenna cells 20 and the TAP cells 25 shown in FIG. 5A, an antenna cell 30 with a TAP function as shown in FIG. 5B is used in this alternative embodiment. Specifically, in the embodiment shown in FIG. 5B, an antenna diode is formed by the doped regions 21A, 21B, extensions 22, and contacts 23 between the power supply lines 11 and the substrate or well as in FIG. 1B. The antenna cell 30 further includes doped regions 26A, 26B and interconnects 27A, 27B. In this embodiment, the doped region 26A is an N-type region defined on an N-well and supplied with a substrate potential VBP through the interconnect 27A. On the other hand, the doped region 26B is a P-type region defined on a P-substrate and supplied with a substrate potential VBN through the interconnect 27B. Arranging such antenna cells 30 with the TAP function as shown in FIG. 5B regularly in the circuit block 52 generates a layout in which the antenna cells 20 and TAP cells 25 such as the ones shown in FIG. 5A are arranged adjacent to each other.

The interval T between the TAP cells 25 is determined mainly by a latch-up rule.

If the interval T is approximately equal to the interval P to be determined mainly by the antenna rule, using the antenna cells 30 such as the one shown in FIG. 5B allows the TAP cells 25 and antenna cells 20 to be placed in a single process step, thus simplifying the physical design process. On the other hand, if a larger number of antenna cells 20 are needed than the TAP cells 25, for example, then the antenna cells 30 with the TAP function as shown in FIG. 5B may all be placed first, and then normal antenna cells 20 may be placed as additional cells. In that case, the circuit block 52 will include both the antenna cells 20 with an adjacent TAP cell 25 and the antenna cells 20 with no adjacent TAP cells 25.

Optionally, the physical design process may also be carried out by placing the antenna cell 20 and the TAP cell 25 adjacent to each other at each predetermined location, instead of using the antenna cells 30 with the TAP function as shown in FIG. 5B.

(Second Alternative Layout Structure)

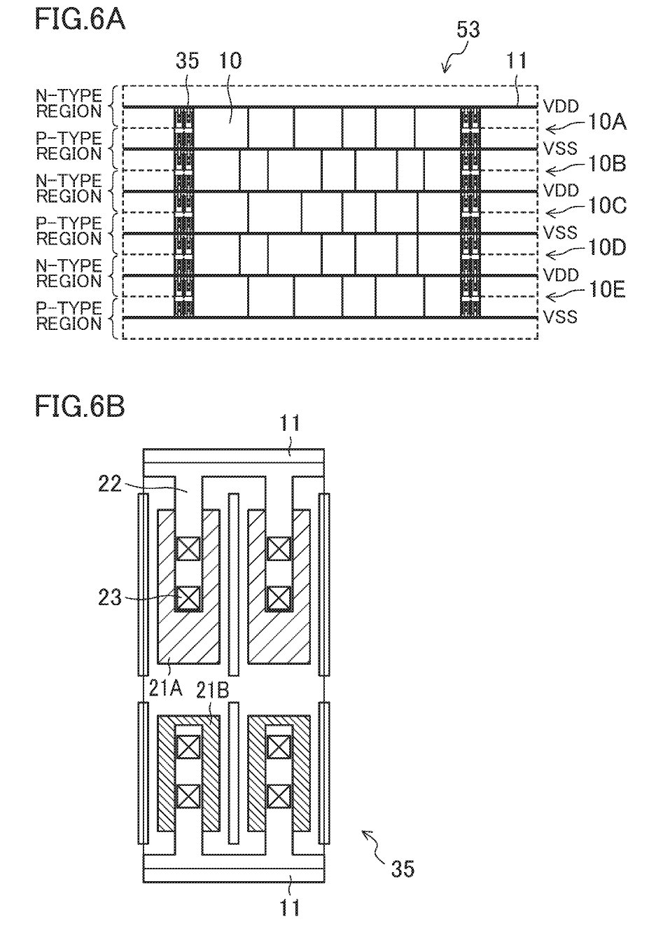

FIG. 6A is a plan view illustrating another alternative exemplary layout structure for a semiconductor integrated circuit according to an embodiment. In FIG. 6A, illustrated is a single circuit block 53 for a semiconductor integrated circuit. As in the circuit block 51 shown in FIG. 1A, five cell rows 10A, 10B, 10C, 10D, and 10E, each being comprised of a plurality of standard cells 10 that are arranged horizontally (corresponding to the first direction) in FIG. 6A, are arranged vertically (corresponding to the second direction) in FIG. 6A. Note that neither the internal configuration nor wiring of the standard cells 10 is illustrated in FIG. 6A. The transistors included in each of those standard cells 10 have the SOI structure described above. Thus, a circuit of SOI transistors is formed in this circuit block 53. Power supply lines 11 for supplying either a supply potential VDD or a ground potential VSS to the circuit block 53 are arranged to extend horizontally between the cell rows. In these cell rows 10A-10E, P-type regions alternate with N-type regions every row. Each of the power supply lines 11 is shared by an associated pair of cell rows located over and under the power supply line. In this embodiment, an N-well to serve as an N-type region is supposed to be defined on a P-type substrate to serve as a P-type region.

In the circuit block 53 shown in FIG. 6A, antenna cells 35 are regularly arranged at both ends of each of the cell rows 10A-10E. FIG. 6B is a plan view illustrating an exemplary configuration for an antenna cell 35. As in the embodiment shown in FIG. 1B, the antenna cell 35 shown in FIG. 6B also includes an antenna diode formed by the doped regions 21A, 21B, extensions 22, and contacts 23. When a physical design process is performed using standard cells, a dummy cell with no logical function may be placed at an end of a cell row. In the configuration shown in FIG. 6A, the antenna cells 35 are arranged as such dummy cells at both ends of each cell row.

The structure shown in FIG. 6A may be adopted when the interval P between the antenna cells placed in accordance with the antenna rule is sufficiently long with respect to the length of each cell row. Also, even if there is no problem with the antenna rule at the level of the circuit block, placing the antenna cells 35 as in the structure shown in FIG. 6A may significantly decrease the likelihood of causing antenna errors at the chip level and save the designer the trouble of going back to an early stage of the physical design process.

In the exemplary configuration shown in FIG. 6A, the antenna cells 35 are arranged at both ends of each of the cell rows 10A-10E. However, this is a non-limiting exemplary embodiment. Alternatively, the antenna cells 35 may also be arranged every predetermined number of rows (e.g., every other row) and/or do not have to be arranged at both ends of the cell rows but may be arranged at either one end of the cell rows. Still alternatively, the antenna cells 40 may also be arranged at one or both ends of the cell rows in only a part, not all, of the circuit block. That is to say, if the antenna cells are arranged at one or both ends of at least three cell rows which are arranged either consecutively or with a predetermined number of rows interposed between them, it can be said that those antenna cells are arranged regularly according to the technique of the present disclosure.

The various exemplary layout structures described above may be adopted in any arbitrary combination. For example, the layout structure shown in FIG. 1A in which the antenna cells 20 are arranged at constant intervals in the first direction in which the standard cells are arranged and in the second direction in which the cell rows are arranged may be combined with the layout structure shown in FIG. 6A in which the antenna cells 35 are arranged at both ends of each cell row.

Also, in the exemplary layout structures described above, each antenna cell is supposed to be a VDD/VSS-compatible antenna cell including both a VDD antenna diode and a VSS antenna diode. However, this is only a non-limiting exemplary embodiment of the present disclosure. Alternatively, VDD antenna cells each including a VDD antenna diode may be arranged separately from VSS antenna cells each including a VSS antenna diode. Furthermore, it does not matter whether any of the VDD and VSS antenna diodes is formed in a P-type region or an N-type region or provided on a well or a substrate.

The present disclosure contributes to eliminating antenna errors from a semiconductor integrated circuit with SOI transistors, and therefore, enhancing the yield of very-large-scale integrated circuits (VLSIs) effectively, for example.

What is claimed is:

1. A layout structure for a semiconductor integrated circuit including silicon-on-insulator (SOI) transistors, the structure comprising:
a circuit block in which a plurality of cell rows, each being comprised of a plurality of standard cells arranged in a first direction, are arranged in a second direction that is perpendicular to the first direction, thereby forming a circuit of the SOI transistors, wherein
the circuit block comprises a plurality of antenna cells, each including an antenna diode formed between a power supply line for supplying power to the circuit block and a substrate or a well, and
in at least a part of the circuit block, the antenna cells are arranged at constant intervals in at least one of the first and second directions.

2. The layout structure of claim 1, wherein
in a first cell row which is one of the plurality of cell rows, at least three antenna cells are arranged at constant intervals.

3. The layout structure of claim 2, wherein
in the first cell row, the antenna cells are all arranged at constant intervals.

4. The layout structure of claim 1, wherein
the plurality of cell rows includes at least three cell rows with the antenna cells, and
the at least three cell rows with the antenna cells are arranged every predetermined number of cell rows.

5. The layout structure of claim 4, wherein
the at least three cell rows with the antenna cells are arranged every other cell row.

6. The layout structure of claim 4, wherein
in the plurality of cell rows, the cell rows with the antenna cells are entirely arranged every predetermined number of cell rows.

7. The layout structure of claim 1, wherein
at least one of the antenna cells arranged in the circuit block is adjacent to a TAP cell having a TAP function of supplying a substrate potential.

8. The layout structure of claim 1, wherein
the plurality of cell rows includes at least three cell rows, each of which includes an antenna cell arranged at one end thereof, and
the at least three cell rows are arranged either consecutively or every predetermined number of cell rows.

9. The layout structure of claim 8, wherein
each of the at least three cell rows includes antenna cells arranged at both ends thereof.
